(19) United States
(12) Patent Application Publication
(10) Pub. No.: US 2004/0158787 A1
(43) Pub. Date: Aug. 12, 2004

(54) Method for implementing self-identifying self-test output

(76) Inventors: Fernando A. Zayas, Loveland, CO (US); Tomas Blazek, Santa Clara, CA (US)

Correspondence Address: SHELDON R. MEYER, ESQ., FLIESLER DUBB MEYER & LOVEJOY LLP, Fourth Floor, Four Embarcadero Center, San Francisco, CA, 94111-4156, US

(21) Appl. No.: 10/364,207

(22) Filed: Feb. 11, 2003

(51) Int. Cl. G01R 31/28

(52) U.S. Cl. 714/733

(57) ABSTRACT

A system and method for translating output received from an electronic device. In one embodiment, the method comprises receiving self test output (STO) from an electronic device, retrieving identification information from the STO, retrieving an output decoder corresponding to the identification information and translating the STO into a specified format using the output decoder. The output decoder may be generated from the same computer code used to generate the output of the electronic device. The output decoder may include descriptive information used to describe the output generated by the electronic device. In one embodiment, the output decoder is generated when the computer code is run on an external processor. In one embodiment, the STO and the output decoder include version information. The STO may be in XML or some other format. The output decoder may be in XML schema or some other format.

### CROSS REFERENCE TO RELATED APPLICATIONS

The present application is related to the following United States patents and patent applications, which patents/applications are assigned to the owner of the present invention, and which patents/applications are incorporated by reference herein in their entirety:

U.S. patent application Ser. No. ______, entitled “SELF-IDENTIFYING SELF TEST OUTPUT SYSTEM”, filed on Feb. ______, 2003, Attorney Docket No. PANA1058US0, filed concurrently herewith.

### COPYRIGHT NOTICE

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### FIELD OF THE INVENTION

The current invention relates generally to testing systems for electronic devices, and more particularly to software self test systems for electronic devices.

### BACKGROUND OF THE INVENTION

Electronic devices such as computer hard drives are manufactured in mass quantities. Part of the manufacturing process includes performing a variety of tests to prepare the hard drive for use and to determine the quality and acceptability of the device. For computer hard drives, the tests often include self tests performed by the drive.

During development of storage devices such as computer hard drives, the results of self tests performed by the drive are typically used to confirm design decisions. The ability to add new self tests and interpret the results quickly for a large population of drives reduces time to volume production and improves the resulting quality.

Hard drive testing is often performed in high volumes. Previously, testing was performed by connecting a computer to a hard drive, testing the hard drive using the computer, and generating a report from the computer. This method had disadvantages in that each hard drive required a computer connection for testing. As advances in computer and integrated circuit technology allowed for smaller computers, external test computers were no longer needed as testing circuits were included as part of the disk drive itself. Internal testing circuits allowed for lower cost testing of hard drives in higher volumes by reducing the external software, including code to implement the self tests. The drives to be tested are loaded with software, including code to implement the self tests. When this self test code is executed by the hard drive circuitry, a self test output file is generated by the hard drive circuitry, and the self test output file is made accessible to outside devices. Once the self test output file is obtained, the contents of self test output are translated and organized in a database or other format to analyze the results of the test.

Though the advances in hardware have provided for less expensive hard drive testing, there are still several disadvantages to the existing hard disk self test process. Currently, the translation of the self test output is done by manually creating a translator program. An illustration of a prior art system 100 for post-processing a self test output file 104 from a hard drive 103 is shown in FIG. 1. Prior art system 100 includes a hard disk drive under test 103, a self test output 104, a translator program 106 and a data base 105. In practice, many hard drives may run self test and produce a multitude of self test outputs. FIG. 1 is simplified to display a single hard drive for purposes of illustration. Hard drive 103 includes circuitry and code (not shown) for performing self test.

Upon performing self tests, each drive produces a corresponding self test output file 104. The self test output file is then translated using a translator program 106. For different tests 100, 101, 102 within the self test output, different routines 107, 108, 109 within the translator program 106 must be manually created to interpret each. For example, routine 107 “Interpret 100” is manually created to interpret test 100 of self test output 104. The translator program 106 is often different for each type of hard drive 103 for which it is compatible. The translator 106 then transmits the interpreted results to a data base 105 (or file or user display, not shown) for storage or further processing. The results can then be analyzed or displayed in a user-readable format such as a database, graph, or other format.

As discussed above, one of the disadvantages of the prior art system is that a translator program must be manually changed to process the self test output and interpret the results for each test and hard drive type. As tests or output formats change, the data, data interpretation, data flags or other data information may change as well. As a result, a change in the test or drive setting requires manually changing corresponding translator programs as well.

What is needed is a system and method for processing the output of hard drive self tests that cover a variety of tests on a variety of drives in a more efficient manner. The system and method should reduce or eliminate programmer modification of the translator when test output changes, when new tests are added, or when new drive types are produced.

### SUMMARY OF THE INVENTION

The present invention provides for processing of electronic device self test output file using a universal translator program. A device is loaded with self test software, executes a series of self tests, and generates a self test output file. The self test output file is received by an external processor and processed by the translator program using a decoder file to produce a formatted decoded output. The decoder file may include descriptive information associated with the self test output generated by the device and the formatted decoded output. The system of the present invention may be implemented using XML as the format for the self test output and an XML Schema as the format for the decoder. Other formats and decoders may also be implemented. In one embodiment, the self test output and decoder include a version number that is maintained throughout the processing chain. The version number may be used to match the self test output to the decoder to automatically process changes in the format of the self test output. In one embodiment, the translator program is implemented on a processor external to the device generating the self test output. In one embodiment, the decoder is generated from the same code used to create the self test output, thereby synchronizing the decoder and the self test output.

### BRIEF DESCRIPTION OF THE DRAWINGS

FIG. 1 is an illustration of a system for performing electronic device self test according to the prior art.

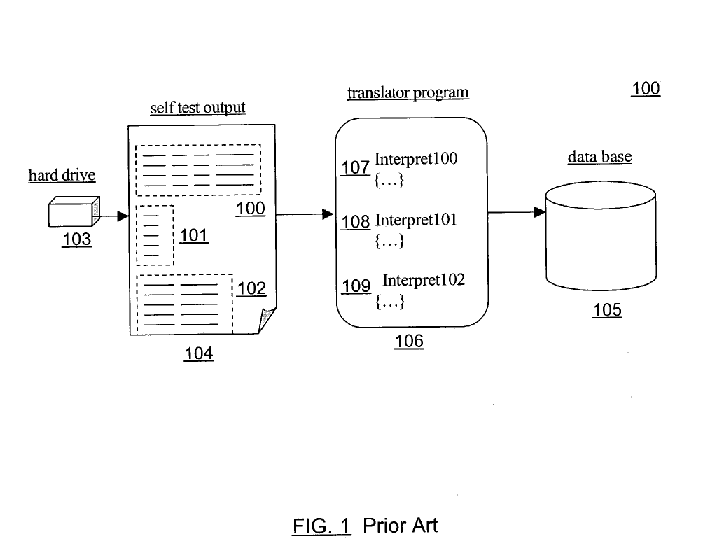

FIG. 2 is an illustration of a system for performing electronic device self tests in accordance with one embodiment of the present invention.

FIG. 3 is an illustration of a system for generating decoder files in two environments in accordance with one embodiment of the present invention.

FIG. 4a is an illustration of a system for generating a self test output file in accordance with one embodiment of the present invention.

FIG. 4b is an illustration of a method for generating a self test output file in accordance with one embodiment of the present invention.

FIG. 5 is an illustration of a method for processing self test output files in accordance with one embodiment of the present invention.

FIG. 6 is an illustration of a method for parsing self test output in accordance with one embodiment of the present invention.

### DETAILED DESCRIPTION

The present invention provides for processing of electronic device self test output using a universal translator program. A device is loaded with self test software, executes a series of self tests, and generates a self test output (STO) file. The STO file is received by an external processor and processed by the translator program using a decoder to produce the formatted decoded output. The decoder may incorporate descriptive information associated with the STO generated by the device and the formatted decoded output. The system of the present invention may be implemented using XML as the format for the STO and an XML Schema as the format for the decoder. Other formats and decoders may also be implemented. In one embodiment, the STO and decoder include a version number that is maintained throughout the processing chain. The version number may be used to match the STO to the decoder to automatically process changes in the format of the STO. In one embodiment, the translator program is implemented on a processor external to the device generating the STO. In one embodiment, the decoder is generated from the same code used to create the STO, thereby synchronizing the decoder and STO.

The present invention is intended to be used with electronic devices that perform self tests. These electronic devices include electronic storage devices (ESD) such as rotating electronic storage devices, optical electronic storage devices, hard drives, and other types of electronic devices. Though one or another type of ESD may be referred to below, it is for purposes of discussion only and not intended to limit the scope of any part of the invention to any particular type of electronic device.

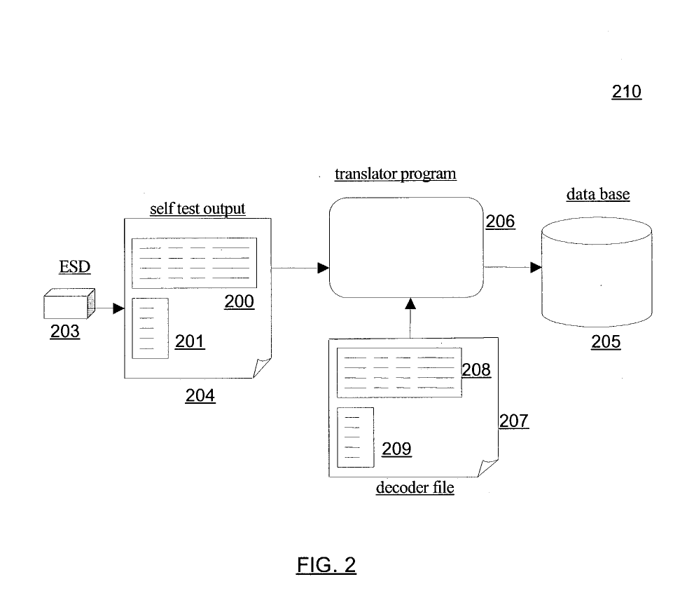

A system for performing tests of devices in accordance with one embodiment of the present invention is illustrated in FIG. 2. FIG. 2 includes an ESD 203, self test output or other output file 204, a translator program 206, a decoder file 207, and a database 205. The self test output 204 includes specific test outputs 200 and 201. For purposes of this disclosure, specific test output is defined to be one or more lines of output generated by a self test within the electronic device, wherein lines of specific test output generated from device self tests comprise the self test output file. The decoder file includes decoder tables 208 and 209. In one embodiment, the translator program is running on a processor external to the ESD (not shown). The decoder file 207 and translator program 206 replace the multiple test and device specific translation routines inside of the translator program of the prior art.

Referring to FIG. 2, the specific test outputs 200 and 201 each correspond to a decoder table 208 and 209, respectively, in the decoder file 207. The specific test outputs 200 and 201 and decoder tables 208 and 209 are tagged with version information to assure the two are in agreement. In one embodiment, each self test generates at least one line of specific test output and version information corresponding to the specific self test. In one embodiment, the version information includes a version number. The decoder tables 208 and 209 are interpreted by the translator program 206 as each specific test output 200, 201 is encountered in the self test output file 204. The specific test outputs 200 and 201 contain data that is described by decoder table 208 and 209, respectively.

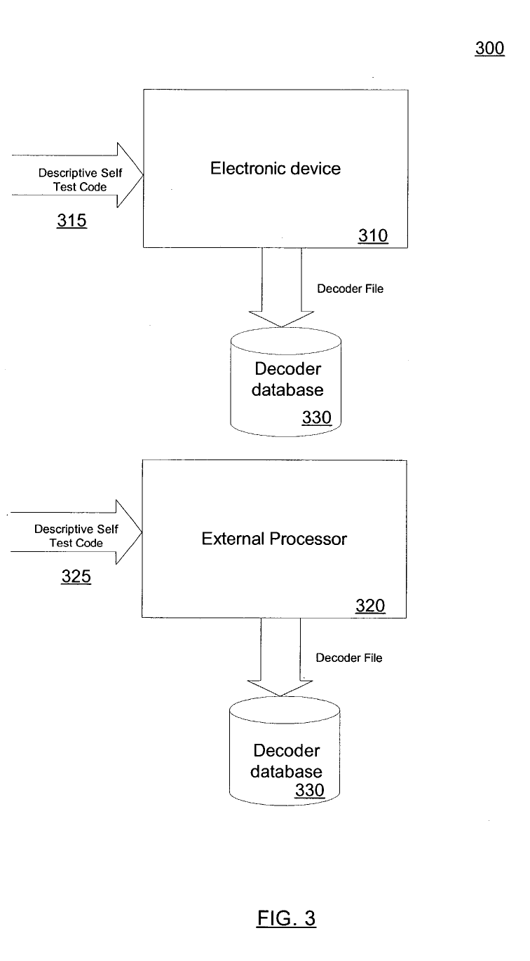

The decoder file 207 of FIG. 2 can be produced in many ways. In one embodiment, the decoder is a text file. The text file may be maintained manually using any text editor. In another embodiment, the decoder file is maintained or produced by the same software that generates the STO. In this embodiment, synchronization may be improved between the decoder and the STO that it describes. FIG. 3 illustrates a system having several embodiments of producing the decoder file. In one embodiment, the decoder file can be produced by running the self test code 315 within the electronic device 310. The decoder file can be produced concurrently with the self test output or at some other time. In another embodiment, the decoder file can be generated by running a program on a processor external to the device under test, wherein the program sources include code from the software running in the device under test as shown by 325. With either system, the decoder file is written to the decoder data base 330 for later use by the translator program 206.

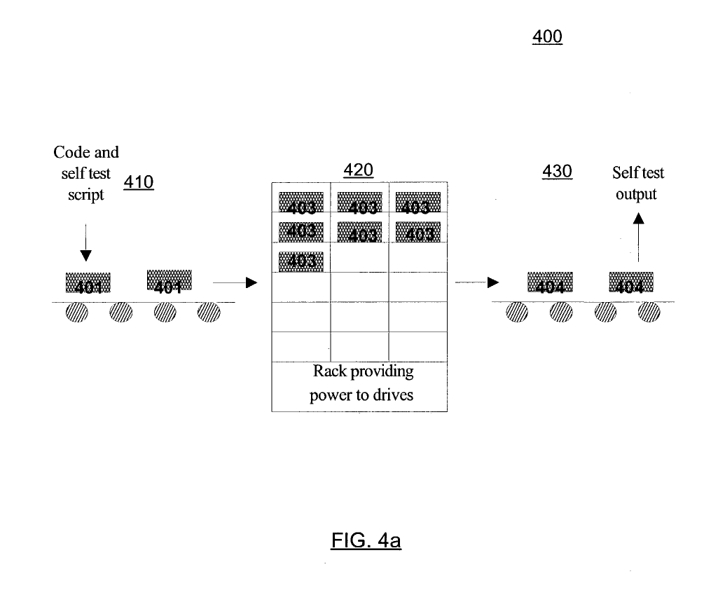

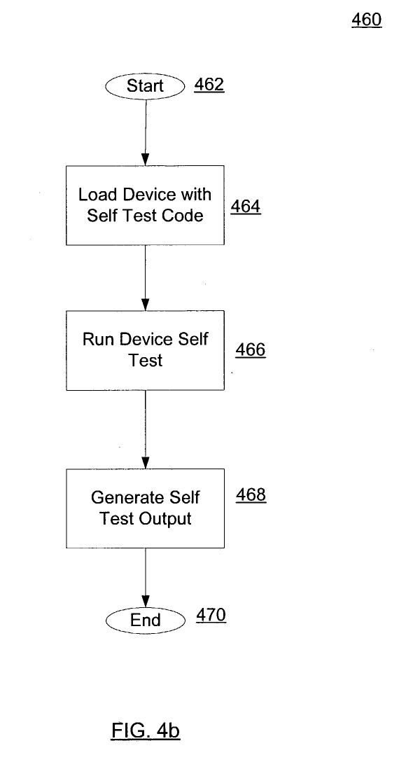

A system for generating an STO file in accordance with one embodiment of the present invention is illustrated in FIG. 4a. System 400 illustrates the STO generation as comprising three different locations, including loading station 410, testing station 420, and STO extracting station 430. Loading station 410 includes ESDs 401 being loaded with code and self test script. Testing station 420 includes ESDs 403 performing self test. STO extracting station 430 includes STO being extracted from ESDs 404. Anyone in the field of testing will understand that STO file generation shown can be done in more or less locations as dictated by the needs of the factory, automation, and communication facilities. A method 460 for generating an output file in accordance with one embodiment of the present invention is illustrated in FIG. 4b. Though the method is discussed for use in testing a STO for ESDs, method 460 may be used in other types of devices implementing other types of tests.

Method 460 begins with start step 462. Self test code and a self test control script may be loaded into a ESD to be tested at step 464. In the embodiment illustrated in FIG. 4a, the code self test script control script is loaded at station 410. The code may be loaded into the ESD over some communication means such as a serial or parallel port. In another embodiment, the code may be preloaded into the memory of the ESD at an earlier time. In one embodiment, the loaded code may include a complete code image and a self test control script. The self test script may be stored in flash within the ESD. In case the code is preloaded, step 464 is optional and need not be performed. An ESD self test is then run at step 466. In the embodiment illustrated in FIG. 4a, the device test is run at station 420. In this embodiment, execution of the self test may include placing the ESD in a rack 405 where at least power is provided, performing initial boot-up of the ESD, loading the code, locating the self test scripts, and running the self-test script. In one embodiment, the script is a series of commands in ASCII for executing ESD self tests. The self tests may include self servo pattern write, defective servo wedge check, defective data block check, and other ESD self tests. Next, after or while the self test is run, the STO is generated at step 468. In the embodiment illustrated in FIG. 4a, the STO is generated at station 430. In one embodiment, each test within the ESD adds result information to the STO, the results taking the form of the specific test output. Operation of method 460 then ends at step 470.

In one embodiment, the STO file has a header, specific test output, and a trailer in ASCII format. The header may include static information known by the ESD. The header may also include keyword information that is modified by a post-processor after the STO file is retrieved from the ESD. The specific test output portion of the STO file includes the output of each scripted self test command concatenated together. The trailer is a summary of the self test and includes information on the tests that were run during self test.

The header portion of the STO is produced by a self test command. An abbreviated example of a header is below:

| | |
|---|---|
| #<Header01_01> | HDA serial number: C22738100038AKPT |
| #<Header01_02> | PCBA serial number: X04260000933 |
| #<Header01_03> | Unload Date: $date$ |

The header typically appears as the first command in a script, but may be invoked at any time. In one embodiment, the header may contain tag information in a “#<TAG>” format. In one embodiment, a tag has a format of XXXXXXXMM_NN. The XXXXXXX portion may include information identifying the test. In the example shown above, the test identification portion indicates that the line displays information related to a header. In one embodiment, the information related to the header is the name of the test that produced this output. MM represents the instance of the command. The instance information relates to the number of times a command is run. Thus, the MM instance information will be 01 for the first time a command is run, 02 for the second time a command is run, and so forth. NN represents a unique output line from that self-test command. Though discussed in reference to a header, any of the header, specific test output, and the trailer may contain tag information.

The header, specific test output, or trailer may also include information intended to aid the readability of the data to humans. In one embodiment, the human-readability information may be contained after the tag information but before the data produced by a command in the self test script. In the example shown above, human readability appears after the closing angle bracket “>” and before the “:” indicator. The information after the “:” indicator may contain data output from a command or keyword information. As discussed above, keyword information may be post-processed after being retrieved from the ESD. The post-processing may include adding information that may not be known to the ESD, such as information indicating the date, time and location of the tests performed. In one embodiment, the keyword information may take the form of replacement tags. In one embodiment, the syntax of the replacement tags is modeled from well known source control systems such as RCS. In the example shown above, a replacement tag is used to indicate the date the STO is unloaded from the ESD and designated as being between two “$” symbols.

The specific test output may contain human-readable information and tagged data. An example of a specific test output is below:

| | Spin | Ramp | Ramp | -Acquire Track- | | |
|---|---|---|---|---|---|---|
| | Time | Loads | Fails | Min | Avg | Max |
| #<RampTest01_00> | 23 | 100 | 1 | 1130 | 1172 | 4095 |
| #<RampTest01_00> | 23 | 100 | 0 | 1104 | 1123 | 2711 |

In one embodiment, the human-readable information includes titles and labels. The titles and headings may be used at the top of desired columns, such as the lines beginning with “Spin” and “Time” in the example shown. Lines in the specific test output may also be tagged. In one embodiment, the specific test output may be tagged in a similar manner as in the header. Attributes for the tagged data may be described in a separate file, such as the decoder, and are discussed in more detail below.

The trailer of the STO is produced by a self-test command. The trailer typically appears as the last command in a script, but may appear anywhere throughout the script. In one embodiment, the trailer summarizes the results of the self test in terms of the name of each test run, how long each test took, the final status of the test, and the line number within the STO, that the test results are located at. A trailer may be tagged in a manner similar to the specific test output and the header. An example of a trailer is shown below:

| | Process | Status | Execute | Line | Fail is |
|---|---|---|---|---|---|
| | -Label- | (hex) | time | number | fatal |
| #<Trailer01_{—} | Header | 00000000 | 000000073 | 00012 | Y |
| 01> | | | | | |
| #<Trailer01_{—} | RampTest | 00000000 | 000002316 | 00079 | Y |
| 01> | | | | | |

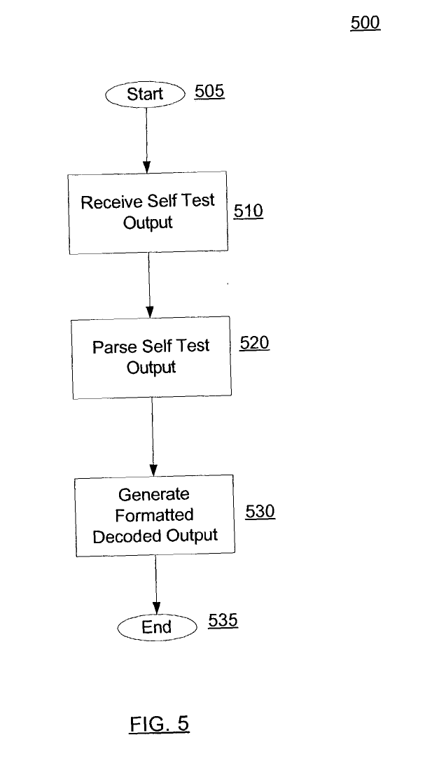

Once the STO file is generated by the ESD, it may be processed. A method 500 for processing STO files in accordance with one embodiment of the present invention is illustrated in FIG. 5. Though the method is discussed for use in processing a STO for ESDs, method 500 may be used in other types of devices implementing other types of tests. Method 500 begins with start step 505. Next, an STO is directly or indirectly received by the translator program from a ESD in step 510. In one embodiment, the STO may be received from the ESD through a serial, parallel or some other port on the ESD.

In one embodiment, receiving the STO may include post-processing the STO to fill in replacement tags. In this embodiment, the replacement tags are filled in such that information regarding the self test performed is provided by an external source. As discussed above, the replacement tag information may relate to the date the data was unloaded, the computer or processor identifier that unloaded the data, location information relating to where the ESD resided during self test (such as a rack number), and other information.

The STO is then parsed at step 520 by a translator program. In one embodiment, parsing the STO involves reading the STO and parsing the document using a translator program and a decoder file. A formatted decoded output (FDO) is generated at step 530 as a parsing result of the STO. In one embodiment, the FDO may be in a format of a database, table, list, graph, or some other format as discussed in more detail below. For every line of tagged output in the STO file self tests, there may be several lines in the self test decoders, with each line including a descriptor for the STO line datum. In one embodiment, the self test decoder descriptors may include a data name, data format, data unit or scaling factor, and default value. In this embodiment, the leading “#” symbol in the STO is replaced in the decoder with either a “!” indicating the decoder line describes a data name, “%” indicating the decoder line describes a data format, “\hat{ }” indicating the decoder line describes a data unit, or “1” indicating the decoder line describes a default value. In one embodiment, lines not tagged are not parsed as they exist only to aid human readability.

The data name may contain letters, numerals, and other glyphs, and can generally by chosen in an arbitrary manner. The data format may include hexadecimal, decimal, or a string. In one embodiment, the format is specified using C-type format. In this case, “% D” may be used to indicate the data is a decimal value. In one embodiment, the number may signed. A data may be formatted as a hexadecimal number with “% X”. In one embodiment, the hexadecimal number is unsigned and does not have “Ox” prepended. A data may be formatted as an error with “% E”. Error codes are formatted in hexadecimal format and may have fields that point to the failing subsystem. A data may be formatted as a string type with “% S”. These designations are only an example of several possible implementations. Other implementations and other data types may be used as will be understood by those in the field.

The data units are given using keywords and an optional multiplier representing the scaling factor. For example, keywords defined for units of data output may include “seconds”, “minutes”, “hours”, “days”, “none”, “datatracks”, “servotracks”, “volts”, “wedge”, “pba” for physical block number, “lba” for logical block number, “amps”, “bps” for bytes for second, and “version” for identifying the version of a self test output. Additionally, a “flag” keyword may be used and followed with brackets enclosing names separated by colons. For the flag keyword, each name in brackets corresponds to a bit position from right to left, starting at bit 0. The flag may be used to determine if a condition represented by a bit is true or false. For example, if a defect list has two bits that indicate whether the defect was a factory defect or a grown defect, the condition could be represented using the unit string flags[grown, defect]. In this example, defect is bit 0 and grown is bit 1 of the flag data. Values for the data could be queried based on the flag name or condition name. In one embodiment, default values are presented as ASCII strings representing numbers or strings in the same format as their corresponding specific test output entries.

A scalar may be used to describe data units. In one embodiment, a scalar is represented as an alphanumeric character and a numerical value, both enclosed in parenthesis. A scalar may include a multiply, divide, and decimal point manipulation. A multiply scalar indicates that the data value is to be multiplied by some value. Thus, “bps (X1000)” indicates that BPS is in kilobytes per second. A divide scalar indicates that the data value is to be divided by a numerical value, such as “seconds (D20)”. Data may be scaled such there are N bits to the right of the decimal point, or that units are in 2^{-N} of the basic unit. For example, measured position may be formatted as “servotracks (Q12)”.

An example of an STO output in accordance with one embodiment of the present invention is shown below:

| | | | | | |
|---|---|---|---|---|---|
| #<RampTest01_00> | 23 | 100 | 1 | 1130 | 4095 |
| #<RampTest01_00> | 23 | 100 | 1 | 1130 | 4095 |
| #<RampTest01_01> | 2 | 22 | 23 | 24 | |

An example of the decoder lines within a decoder table used to parse the above STO output in accordance with one embodiment of the present invention is shown below:

| | | | | | |
|---|---|---|---|---|---|
| !<RampTest??_00> | SpinUpTime | RampLds | RampFails | MinAcqTrk | MaxAcqTrk |
| %<RampTest??_00> | %d | %d | %d | %d | %d |
| \hat{ }<RampTest??_00> | 0 | 0 | 0 | 0 | 0 |
| &<RampTest??_00> | seconds (D20) | none | none | servotracks | servotracks |
| !<RampTest??_01> | SpinUps | MinSpinTime | AvgSpinTime | MaxSpinTime | |
| %<RampTest??_01> | %d | %d | %d | %d | |
| \hat{ }<RampTest??_01> | 0 | 0 | 0 | 0 | |
| &<RampTest??_01> | none | seconds (D20) | seconds (D20) | seconds (D20) | |

In one embodiment, a version number may be assigned to each specific test output or other portions of the STO. In this embodiment, the version number may be maintained at all levels of processing the STO. In one embodiment, the version information may be included using a unit keyword “version” as shown below:

#<RampTest01_{—}02> Version: 107

In the embodiment illustrated above, the number “107” indicates the version number of the RampTest self test command. The version number may be maintained in the decoder file as well as any database created using the STO and the decoder file. Maintaining the version number throughout the process provides a means for associating test output, decoder files, and data base tables. In one embodiment, a new version number may be used when a self test command is changed, either from a change in output, algorithm, or some other reason. Though the version number may change from changes in the specific test output, the translator program 206 does not need to be modified for each change.

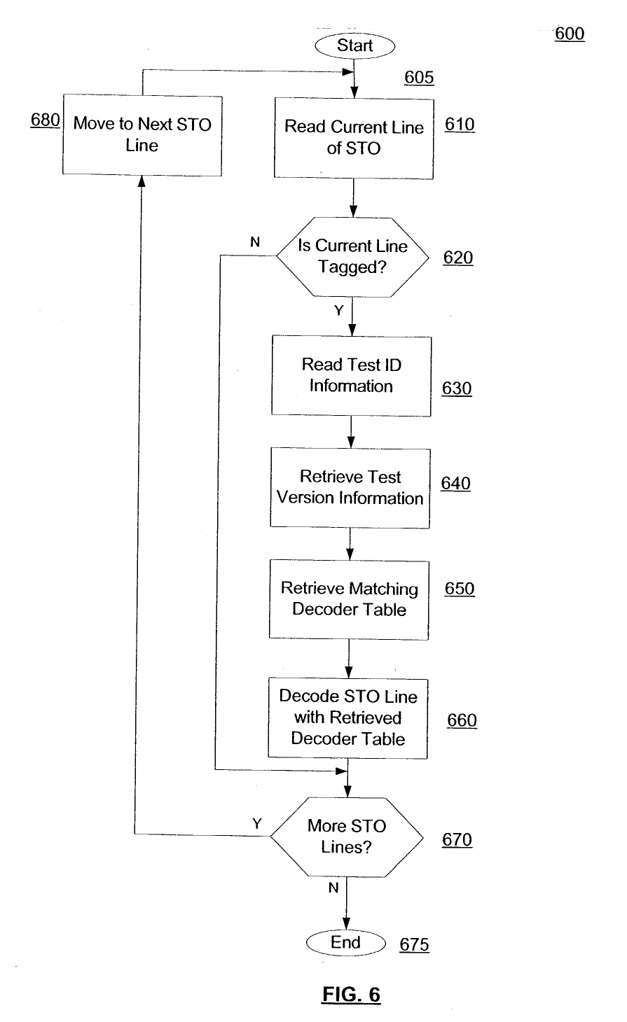

As discussed above, once an STO file is received by an external processor, the STO is parsed using a decoder file holding version compatible test specific decoder tables that correspond to particular specific self tests. A method 600 for parsing STO in accordance with one embodiment of the present invention is illustrated in FIG. 6. Though the method is discussed for use in parsing an STO for ESDs, method 600 may be used in other types of devices implementing other types of tests.

Method 600 begins with start step 605. Next the current line of an STO is read at step 610. Initially, this is the first line of the STO. The translator program then determines if the current line read from the STO is tagged. In one embodiment, the current line is tagged if a specific tag format is recognized in any of a header, specific test output, or trailer. If the current line is not deemed tagged in step 620, operation continues to step 670 thus ignoring the line. If the current line is tagged, operation continues to step 630. Test identification information is read at step 630. In one embodiment, the test identification information may be the “XXXXXXX” portion of a XXXXXXXMM_NN formatted tag for the line read. The test identification information may represent the name of the test or some other information. Next, a version number is retrieved in step 640. In one embodiment, the version number is retrieved from a look-up table that is accessible by the translator program 206 in FIG. 2. In this embodiment, all self tests within an STO file are matched with a version number prior to the parsing of the STO file. The look-up table of STO files and matching version numbers is available to the translator program as a result of a pre-parsing output produced by the ESD or in some other manner such that the matching information is available to the translator program. In another embodiment, retrieving the test version information is not needed as the test identification information retrieved in step 630 is unique.

Once test identification information and a test version number are known, the translator program 206 retrieves a matching decoder table in step 650. In this embodiment, the translator program has access to multiple decoder tables within a decoder file. The translator program 206 then decodes the current STO line with the matching decoder table in step 660. Operation then continues to step 670 where the translator program determines if there are more lines in the STO. If more lines exist in the STO at step 670, operation continues to step 680 where the translator program prepares to read the next STO line. If no additional STO lines exist at step 670, operation ends at step 675. As understood by those skilled in the art, other methods for parsing STO lines using a pool of decoder files containing descriptors are possible and considered within the scope and spirit of the present invention. Additionally, specific test output within an STO file may have multiple consecutive lines corresponding to the output of a single test. In this situation, a single matched table may be used to decode the multiple consecutive lines of the STO. In this embodiment, step 660 may be repeated until a specific test output does not match the current decoder table.

In one embodiment, the decoder file may be generated using the same software that creates the STO. This provides a method for ensuring the STO and decoder file remain synchronized. In one embodiment, the ESD may be configured to execute the self tests and then be queried for the decoder file descriptive information by an external processor. In another embodiment, the decoder file is generated by including portions of the software that generates the STO into a program run on an external processor. In this embodiment, the external processor would then generate the decoder file from the STO software portions that were loaded. Each of these embodiments is illustrated in FIG. 3.

In one embodiment of the present invention, the STO is implemented in XML. In this case, the decoder may be implemented as an XML Schema. Thus, the data description information, which may include name, format and units, are described and processed using XML instructions and rules as is known in the art. An example of self test output in XML format in accordance with one embodiment of the present invention is illustrated below.

<?xml version=“1.0” encoding=“UTF-8”?>
<RampTest>

<RampTestIteration>

<SpinUpTime>23</SpinUpTime>
<RampLds>100</RampLds>
<RampLdFails>1</RampLdFails>
<MinAcqTrk>1130</MinAcqTrk>
<MaxAcqTrk>4095</MaxAcqTrk>

</RampTestIteration>
<RampTestIteration>

<SpinUpTime>23</SpinUpTime>
<RampLds>100</RampLds>
<RampLdFails>1</RampLdFails>
<MinAcqTrk>1130</MinAcqTrk>
<MaxAcqTrk>4095</MaxAcqTrk>

</RampTestIteration>
<RampTestIteration>

<SpinUpTime>22</SpinUpTime>
<RampLds>100</RampLds>
<RampLdFails>1</RampLdFails>
<MinAcqTrk>1130</MinAcqTrk>
<MaxAcqTrk>4095</MaxAcqTrk>

</RampTestIteration>
<RampTestSummary>

<SpinUps>2</SpinUps>
<MinSpinUpTime>22</MinSpinUpTime>
<AvgSpinUpTime>23</AvgSpinUpTime>
<MaxSpinUpTime>23</MaxSpinUpTime>

</RampTestSummary>

</RampTest>

An example of an XML schema used to interpret the XML STO in accordance with one embodiment of the present invention is shown below. In one embodiment, descriptive information, including units, could be embedded in the schema as random text or using other techniques as understood by those skilled in the art.

<xsd:schema xmlns:xsd=“http://www.w3.org/2001/XMLSchema”>
<annotation>

<documentation xml:lang=“en”>

Definition of RampLoad test result data

</documentation>

</annotation>
<xs:complexType name=“RampTest”>

<xs:sequence>

<xs:element name=“RampTestIteration”>

| | |
|---|---|
| <xs:attribute name=“SpinUpTime” | type=“xs:integer”/> |
| <xs:attribute name=“RampLds” | type=“xs:integer”/> |
| <xs:attribute name=“RampLdFails” | type=“xs:integer”/> |
| <xs:attribute name=“MinAcqTr” | type=“xs:integer”/> |
| <xs:attribute name=“MaxAcqTr” | type=“xs:integer”/> |

</xs:element>

</xs:sequence>
<xs:element name=“RampTestSummary“>

The present invention provides for processing of electronic device self test output using a translator program that acts as a universal parser. A device is loaded with self test code, executes a series of self tests, and generates an STO file. The STO file is received by an external processor, processed by a parsing program using a decoder file that is version tagged to match the STO file. The decoder file includes descriptive information in the form of decoder tables for the STO file generated by the device. In one embodiment, the system of the present invention may be implemented using an XML format STO and an XML Schema decoder. In another embodiment, other formats and parsers may be used for the STO and decoder tables. The STO may include a version number that is maintained throughout the processing chain and included in formatted data derived from the versioned STO. In one embodiment, the translator program is implemented by a processor external to the device generating the STO. The decoder file used by the translator program may be generated from the same code used to create the STO.

Other features, aspects and objects of the invention can be obtained from a review of the figures and the claims. It is to be understood that other embodiments of the invention can be developed and fall within the spirit and scope of the invention and claims.

The foregoing description of preferred embodiments of the present invention has been provided for the purposes of illustration and description. It is not intended to be exhaustive or to limit the invention to the precise forms disclosed. Obviously, many modifications and variations will be apparent to the practitioner skilled in the art. The embodiments were chosen and described in order to best explain the principles of the invention and its practical application, thereby enabling others skilled in the art to understand the invention for various embodiments and with various modifications that are suited to the particular use contemplated. It is intended that the scope of the invention be defined by the following claims and their equivalence.

In addition to an embodiment consisting of specifically designed integrated circuits or other electronics, the present invention may be conveniently implemented using a conventional general purpose or a specialized digital computer or microprocessor programmed according to the teachings of the present disclosure, as will be apparent to those skilled in the computer art.

Appropriate software coding can readily be prepared by skilled programmers based on the teachings of the present disclosure, as will be apparent to those skilled in the software art. The invention may also be implemented by the preparation of application specific integrated circuits or by interconnecting an appropriate network of conventional component circuits, as will be readily apparent to those skilled in the art.

The present invention includes a computer program product which is a storage medium (media) having instructions stored thereon/in which can be used to program a computer to perform any of the processes of the present invention. The storage medium can include, but is not limited to, any type of disk including floppy disks, optical discs, DVD, CD-ROMs, microdrive, and magneto-optical disks, flash memory devices, magnetic or optical cards, nanosystems (including molecular memory ICs), or any type of media or device suitable for storing instructions and/or data.

Stored on any one of the computer readable medium (media), the present invention includes software for controlling both the hardware of the general purpose/specialized computer or microprocessor, and for enabling the computer or microprocessor to interact with a human user or other mechanism utilizing the results of the present invention. Such software may include, but is not limited to, device drivers, operating systems, and user applications.

Included in the programming (software) of the general/specialized computer or microprocessor are software modules for implementing the teachings of the present invention, including, but not limited to, generating and processing STO tests for hard drive and other electronic devices.

1. A computer for decoding self test output, the computer comprising:
an input means, the computer configured to receive a self test output through said input means, the self test output including identification information and a plurality of specific test output lines;
a memory, wherein translator program computer code is stored in said memory; and
a processor, the processor configured to decode the self test output when the processor is loaded with the translator program code, the translator program computer code including:
computer code for receiving the self test output;
computer code for retrieving the identification information from the self test output;
computer code for retrieving a decoder information associated with the identification information; and
computer code for decoding the self test output into a formatted data output using the decoder information.

2. The computer of claim 1 wherein computer code for receiving the self test output includes:
computer code for receiving a plurality of lines of specific test output, the plurality of lines of specific test output forming a self test output.

3. The computer of claim 1 wherein the self test output is in extensible markup language.

4. The computer of claim 1 wherein the decoder information is extensible markup language schema.

5. The computer of claim 1 wherein identification information includes version information, the computer code for retrieving identification information from the output including computer code for retrieving version information.

6. The computer of claim 1 wherein identification information includes test name information, the computer code for retrieving identification information from the output including computer code for retrieving test name information.

7. The computer of claim 1 wherein computer code for retrieving decoder information includes:
computer code for retrieving a decoder table, the decoder table associated with the identification information and residing in a decoder file.

8. The computer of claim 7 wherein the decoder table includes data name information.

9. The computer of claim 7 wherein the decoder table includes data format information.

10. The computer of claim 7 wherein the decoder table includes data unit information.

11. The computer of claim 7 wherein the decoder table includes default value information.

12. The computer as claimed in claim 1 wherein computer code for retrieving identification information from the self test output includes:
computer code for determining if the self test output is tagged with identification information; and
computer code for retrieving identification information from the self test output if the self test output is tagged with identification information.

13. The computer as claimed in claim 12 wherein computer code for determining if the self test output is tagged with identification information includes:
computer code for determining if the self test output is tagged with a self test name information.

14. The computer as claimed in claim 1 wherein the translator program computer code further includes:
computer code for storing the formatted data output to a database, the formatted data output including a at least a portion of the identification information.

15. An electronic device comprising:
memory, said memory operable to store computer code configured to generate a self test output file;
a processor, said processor configured to load and execute the computer code.
an input means, said input means configured to receive the computer code;
an output means, said output means configured to transmit a self test output, the self test output including:
identification information; and
a plurality of specific self test output lines, the self test output configured to be decoded by a decoder file.

16. The method of claim 15 wherein at least one of the plurality of self test output lines includes tag information, the tag information including the identification information.

17. The method of claim 16 wherein the identification information includes version information.

18. The method of claim 16 wherein the identification information includes test name information.

19. The electronic device of claim 16 wherein said computer code is configured to generate the decoder file, the decoder file configured to decode specific self test output lines having tag information.

20. The electronic device of claim 19 wherein the decoder file includes at least one decoder table, the decoder table associated with the identification information.

21. The electronic device of claim 20 wherein the decoder table includes data name information.

22. The electronic device of claim 20 wherein the decoder table includes data format information.

23. The electronic device of claim 20 wherein the decoder table includes data unit information.

24. The electronic device of claim 20 wherein the decoder table includes default value information.
